(19) United States
(12) Patent Application Publication
(10) Pub. No.: US 2006/0279366 A1
(43) Pub. Date: Dec. 14, 2006

(54) Generator of a pseudo-random digital flow

(75) Inventors: Edith Kussener, Le Revest Les Eaux (FR); Vincent Telandro, Toulon (FR); Fabien Chaillan, Sanary Sur Mer (FR)

Correspondence Address: GRAYBEAL JACKSON HALEY LLP;Suite. 350, 155-108th Avenue N.E., Bellevue, WA, 98004-5973, US

(73) Assignees: STMicroelectronics SA; UNIVERSITE D'AIX-MARSEILLE I

(21) Appl. No.: 11/441,923

(22) Filed: May 25, 2006

(30) Foreign Application Priority Data
May 25, 2005 (FR) 05/51377

(51) Int. Cl. H03B 29/00

(52) U.S. Cl. 331/78

(57) ABSTRACT

A method and a circuit for generating a pseudo-random digital flow comprising an oscillator, the biasing of which is controllable by an analog bias source controlled by a signal with continuous amplitude and time variatons.

### PRIORITY CLAIM

This application claims priority from French patent application No. 05/51377, filed May 25, 2005, which is incorporated herein by reference.

### BACKGROUND

1. Technical Field

An embodiment of the present invention generally relates to electronic circuits and more specifically to the generation of a pseudo-random digital flow.

An embodiment of the present invention particularly applies to secure circuits, for example, of smart card type, implementing ciphering, authentication, identification, etc. algorithms requiring pseudo-random data.

Another example of application of an embodiment of the present invention relates to the generation of a clock signal with pseudo-random frequency jumps.

2. Discussion of the Related Art

Many methods and circuits for generating in hardware or software fashion pseudo-random digital flows are known.

An embodiment of the present invention more specifically relates to generators using hardware means rather than algorithms executed by a microcontroller, software methods generally suffering from being deterministic.

Among known hardware solutions, some implement exclusively digital means, for example, a linear feedback shift register (LFSR). Others exploit an analog source, for example, a natural noise source linked to the thermal noise of a resistor or of a diode, or the sampling of a relatively fast oscillator by a relatively slow oscillator.

Another solution to which an embodiment of the present invention more specifically applies uses a controllable-bias oscillator.

FIG. 1 shows in the form of blocks a conventional example of a circuit 1 for generating a pseudo-random signal Vout based on the biasing of an oscillator 2 (OSC) supplied by a D.C. voltage Vdd. This biasing is performed by means of several current sources 31, 32, 33, 3n-1, and 3n connected in parallel between a terminal 21 for sampling a bias current and the ground, each current source being individually in series with a control switch K1, K2, K3, Kn-1, and Kn. The n switches K1 are controlled by a digital circuit 4 of microcontroller type (μC) having the function of causing pseudo-random time jumps in the biasing of oscillator 2 by the control of the different switches. Generally, current sources 3i absorb fixed currents of different values, each of them being individually and separately controlled by microcontroller 4 so that the current sources bias the oscillator individually and successively. A maximum of 2ⁿ−1 combinations is thus obtained. Oscillator 2 is, for example, a ring oscillator.

FIG. 2 illustrates in a timing diagram an example of the shape of signal Vout provided by generator 1 of FIG. 1. The value of the bias current conditions during successive periods T1 (source 31), T2 (source 32 of a current greater than that of source 31), T3 (source 33 of a current smaller than that of source 31), etc. of the oscillator, and the switchings (times t10, t11, t12, and t13) between the current sources condition the respective durations of the pulse trains of periods T1, T2, T3, etc. Signal Vout is a digital signal of pseudo-random frequency and with pseudo-random time jumps.

If, as shown, the maximum interval of time between switchings of the switches is greater than the stabilizabon time of oscillator 2, a dock signal with pseudo-random frequency jumps is obtained.

Conversely, if the maximum interval of time between switchings of the switches is shorter than the oscillator stabilizabon time, a pseudo-random digital signal which, when exploited at a fixed frequency by a downstream circuit (not shown), forms a pseudo-random digital data signal, is obtained.

A disadvantage is that the control of switches Ki performed by microcontroller 4 utilizes a control algorithm to control a determined number of bias sources. Such an algorithm is necessarily deterministic, which adversely affects the random character of the generated digital flow.

### SUMMARY

An embodiment of the present invention is a generator of a pseudo-random digital flow which overcomes all or some of the disadvantages of known oscillators.

An embodiment of the present invention more specifically is a solution based on a controllable-bias amplifier.

Another embodiment of the present invention is a digital data generator based on such an oscillator which overcomes all or part of the disadvantages of known generators.

Another embodiment of the present invention makes the generated flow independent from discrete values of different current sources.

An embodiment of the present invention provides a generator of a pseudo-random digital flow comprising a controllable-bias oscillator, comprising an analog bias source controlled by a signal with continuous amplitude and time variations.

According to an embodiment of the present invention, said bias source is controlled by a circuit for sampling/holding a periodic signal with more than two amplitude levels, the sampling times being set by a threshold detector of a pseudo-random signal source.

According to an embodiment of the present invention, the periodic signal is provided by a triangular generator.

According to an embodiment of the present invention, the amplitude range of the bias source is set by the amplitude of the triangular signal.

According to an embodiment of the present invention, said source of a pseudo-random signal is a chaotic oscillator, preferably with several scroll attractors.

According to an embodiment of the present invention, the range of the time variations of the biasing of the controllable-bias oscillator is set by the range of possible intervals between the jumps from one scroll attractor to another of the chaotic oscillator.

According to an embodiment of the present invention, the maximum value of the range of time variations of the biasing of the controllable-bias oscillator is selected to be smaller than the stabilizabon time of this oscillator, to obtain a generator of pseudo-random digital data.

According to an embodiment of the present invention, the minimum value of the range of time variations of the biasing of the controllable-bias oscillator is selected to be greater than the stabilizabon time of this oscillator to obtain a clock signal generator with pseudo-random frequency jumps.

Another embodiment of the present invention is a method for controlling a generator of a pseudo-random digital flow, comprising the control of the biasing of the biasable oscillator by means of a stepped signal where the duration of the steps varies in pseudo-random continuous fashion within a given interval and where the amplitude of the steps also varies in pseudo-random and continuous fashion within a given interval.

### BRIEF DESCRIPTION OF THE DRAWINGS

Features and advantages of embodiments of the present invention will be discussed in detail in the following non-limitng description of specific embodiments in connection with the accompanying drawings.

FIGS. 1 and 2, previously described, show the state of the art and a problem to solve.

FIG. 3 is a view in the form of blocks of a functional embodiment of an oscillator according to the present invention.

FIG. 4 shows an example of the shape of a control signal of a current source of a pseudo-random oscillator according to an embodiment of the present invention.

FIG. 5 shows in the form of blocks an embodiment of a circuit for controlling a pseudo-random oscillator according to the present inventon.

FIG. 6 is an example of a pseudo-random source of the circuit of FIG. 5 according to an embodiment of the inventon.

FIGS. 7A, 7B, 7C, 7D, and 7E illustrate, in timing diagrams, an example of the shape of signals at different points of the circuit of FIG. 5 according to an embodiment of the inventon.

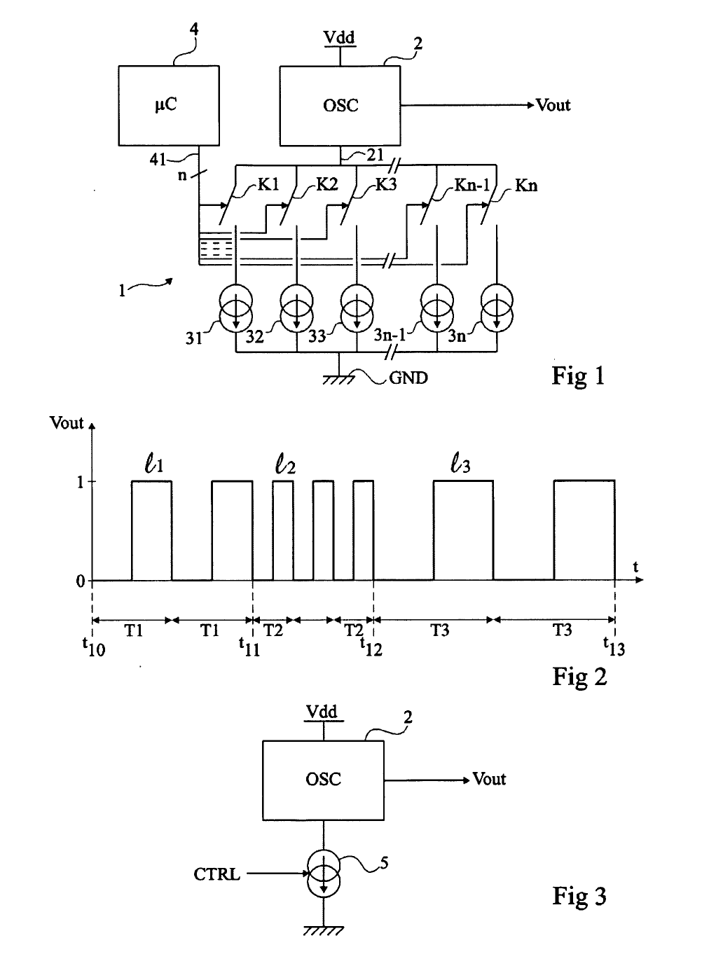

### DETAILED DESCRIPTION

Same elements have been designated with same reference numerals in the different drawings. For clarity, only those elements which are useful to the understanding of embodiments of the present invention have been shown in the drawings and will be described hereafter. In particular, what exploitabon is made of a pseudo-random digital signal generated by an oscillator according to an embodiment of the present invention has not been detailed, such a signal the present invention being compatible with any conventonal exploitabon of a pseudo-random flow.

A feature of an embodiment of the present inventon is to replace the current sources digitally controlled to bias an oscillator with a current source controllable by a pseudo-random analog signal.

Another feature of an embodiment of the present inventon is to control this current source to obtain a bias current with continuous amplitude and time variabons.

Preferably, the control signal of the current source is made equiprobable.

FIG. 3 shows an embodiment of a pseudo-random digital flow generator according to the present inventon. It comprises an oscillator 2 (OSC) supplied by a voltage Vdd providing digital flow Vout. The oscillator 2 is biased by a current source 5 analogically controlled by means of a signal CTRL likely to vary the amplitude and the frequency in pseudo-random fashion over continuous limited intervals.

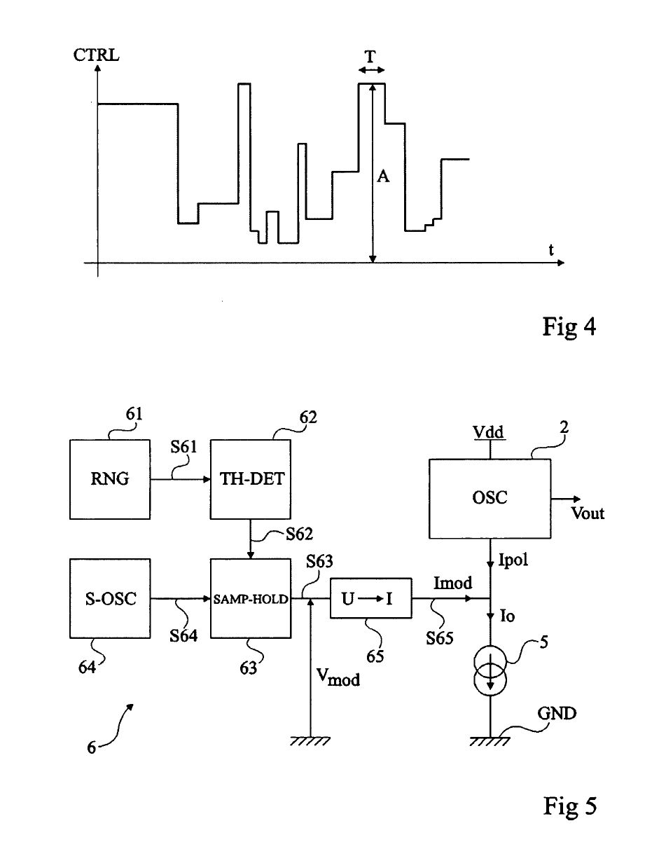

FIG. 4 illustrates an example of a signal CTRL for controlling current source 5 of FIG. 3.

According to this embodiment of the present invention, signal CTRL is a stepped signal likely to vary, not only in amplitude, but also in switching frequency. Time width T of the different steps varies in pseudo-random fashion over a continuous limited interval and amplitude A of these steps also varies in pseudo-random fashion over a continuous limited interval. As a result, the output signal of oscillator 2 exhibits frequency jumps occurring at pseudo-random times, between frequency values which are themselves pseudo-random.

With a maximum value of the intervals between frequency jumps (and thus a selected frequency variation range) smaller than or equal to the oscillator stabilization time, output signal Vout can be sampled at fixed frequency to obtain a pseudo-random digital data flow.

With a minimum value of the intervals between frequency jumps greater than the oscillator stabilization time, signal Vout forms a clock signal with pseudo-random frequency jumps.

FIG. 5 shows in the form of blocks an example of the architecture of a pseudo-random generator according to an embodiment of the present invention. It shows oscillator 2 biasable by current source 5 between a terminal of application of supply voltage Vdd and ground GND.

In this example, the circuit for generating control signal CTRL comprises a pseudo-random signal source 61 (RNG), a detector 62 of one or several thresholds (TH-DET), a sample-and-hold circuit 63 (SAMP-HOLD), an analog signal generator 64 (S-OSC), a voltage-to-current converter 65 (U→I), for example, a MOS transistor of a transconductance amplifier (OTA), and a source 5 of a constant current /0. Source 5 sets the average frequency of oscillator 2. The variation of bias current /pol of oscillator 2 is obtained by varying current /mod provided by element 65, which adds to fixed current /0.

Output S61 of pseudo-random source 61 is connected to the input of threshold detector 62. As a result, each crossing of a threshold by pseudo-random signal S61 translates as a state switching at output S62 of detector 62. Preferably, the threshold detector detects the crossings of a same threshold (or of several thresholds) in both directions by signal S61. Output S62 switches from an inactive state to an active state for a short time on each crossing of this threshold. Signal S62 controls sample-and-hold circuit 63 having its input connected to output S64 of analog signal generator 64. Output S63 of the sample-and-hold circuit provides a voltage Vmod to converter 65, the output S65 of which provides modulation current /mod.

Functionally, the output of generator 64 is sampled at pseudo-random times by sample-and-hold circuit 63 each time the output signal of source 61 crosses the threshold set by detector 62.

According to an embodiment of the present inventon, generator 61 is a chaotic oscillator. The signals generated by this type of oscillator have the advantage of being pseudo-random and very sensitive to variatons in the initial conditions (butterfly effect). The initial conditions are set by physical parameters sensitive to the operation conditions, and especially to temperature. Sequences different from one another are then obtained. An oscillator with two scroll attractors where the passing from one scroll to another is performed in unanticipated fashion according to the initial conditions may be used. The intrinsic defects of the oscillator (phase jitter, thermal noise, etc.) also take part in the increasing of the entropy of the generated digital flow.

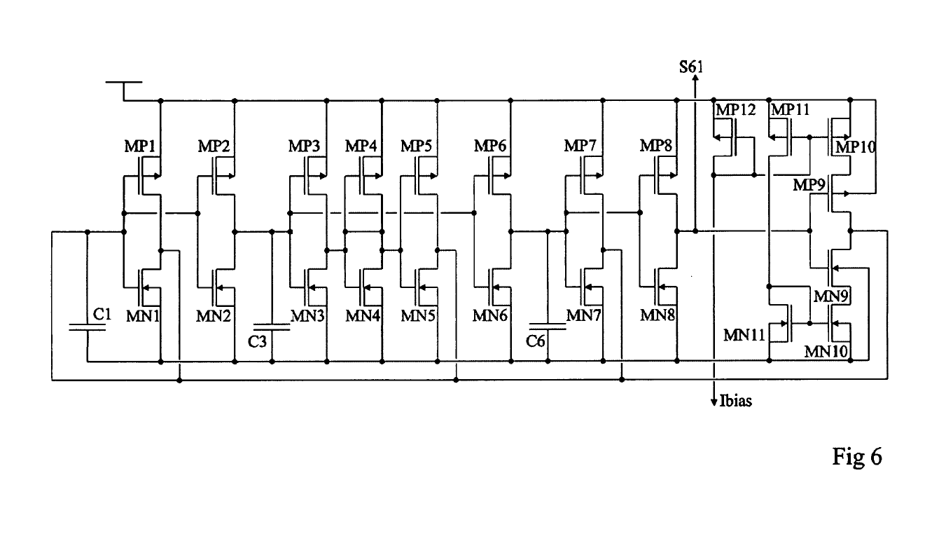

FIG. 6 is a schematic diagram of a chaotic oscillator 61 with two scroll attractors according to an embodiment of the invention. Such an oscillator comprises, for example, nine parallel branches of MOS transistors between a terminal of application of voltage Vdd and the ground. Eight branches each comprise a P-channel MOS transistor MP1 to MP8 in series with an N-channel MOS transistor MN1 to MN8. A ninth branch comprises in series two P-channel MOS transistors MP10 and MP9, and two N-channel MOS transistors MN9 and MN10. The gate of each transistor MPj (j ranging between 1 and 9) is connected to the gate of the corresponding N-channel transistor MNj. Three capacitors C1, C3, and C7 ground the respective common gates of transistors MP1 and MN1, MP3 and MN3, MF7 and MN7. The gates of the transistors of the first two branches are connected together as well as the gates of the transistors of the third and sixth branches, fourth and fifth branches, and seventh and eighth branches. The junction point of transistors MP1 and MN1 is connected to the gates of these transistors. The junction point of transistors MP2 and MN2 is connected to the gates of the third branch. The junction point of transistors MP3 and MN3 is connected to the gates of the fourth and fifth branches, and to the junction point of transistors MP4 and MN4. The respective junction points of transistors MP5 and MN5, MP7 and MN7, and MP9 and MN9, are connected to the gates of the first branch. The junction point of transistors MP6 and MN6 is connected to the gates of the seventh and eighth branches. The junction point of transistors MP8 and MN8 is connected to the gates of transistors MP9 and MN9 of the ninth branch and forms output S61 of the chaotic oscillator. Transistors MP10 and MN10 are respectively mirror-assembled on a P-channel MOS transistor MP12 and an N-channel MOS transistor MN11, transistor MN11 being in series with a transistor MP11 assembled as a current mirror on transistor MP12. The drain of transistor MP12 is connected to a bias source (not shown) to which it provides a current /bias. The respective bulks of the P-channel transistors are connected to voltage Vdd while the bulks of the N-hannel transistors are grounded.

The circuit of FIG. 6 is an example only and other chaotic oscillators may be envisaged, the practical forming of a chaotic oscillator being known per se and described, for example, in the following articles, which are incorporated by reference:

“Construction of C1asses of Circuit-Independent Chaotic Oscillators Using Passive-Only Nonlinear Devices” by Ahmed S. Elwakil and Michael Peter Kennedy, published in March 2001 in IEEE Transactions on Circuits and Systems-I: Fundamental Theory and Applications, vol. 48, N° 3 (pages 289-307);

“MOS Realization of the Double-Scroll-Like Chaotic Equation”, by Ahmed G. Radwan, Ahmed M. Soliman, and Abdel-Latif EI-Sedeek, published in February 2003 in IEEE Transactions on Circuits and Systems-I: Fundamental Theory and Applications, vol. 50, N° 2 (pages 285-288); and

“Design and Analysis of Multiscroll Chaotic Attractors From Saturated Function Series” by Jinhu Lü, Guanrong Chen, Xinghuo Yu, and Henry Leung, published in December 2004 in IEEE Transactions on Circuits and Systems-l: Fundamental Theory and Applications, vol. 51, N° 12 (pages 2476-2490).

The number of thresholds detected by circuit 62 depends on the number of scroll attractors of the chaotic oscillator 61. In the case of an oscillator with two scroll attractors, a single threshold equal to approximately half the maximum voltage amplitude of signal S61 will be detected.

As a variation, the chaotic oscillator may be replaced with a microprocessor provided with a pseudo-random digital algorithm of generation of a signal intended for threshold detector 62.

According to an embodiment of the present invention, analog signal generator 64 is a triangular signal generator which has the advantage of bringing an equiprobable character to the sampling times of circuit 63. The forming of a triangular signal generator is within the abilities of those skilled in the art. As a variation, generator 64 provides any periodic signal (for example, a sinusoidal or stepped signal), with more than two amplitude levels to exclude a rectangular signal (pulse train), which may destroy the pseudo-random character of the sampling.

Signal S64 is provided by analog generator 64 to the sample-and-hold circuit. Output signal S63 of the sample-and-hold circuit is averaged at the input of converter 65, which converts into current the intervals with respect to the detected average value. Converter 65 is, for example, an operational transconductance amplifier (OTA) used in a range of linear variation of the transconductance gain.

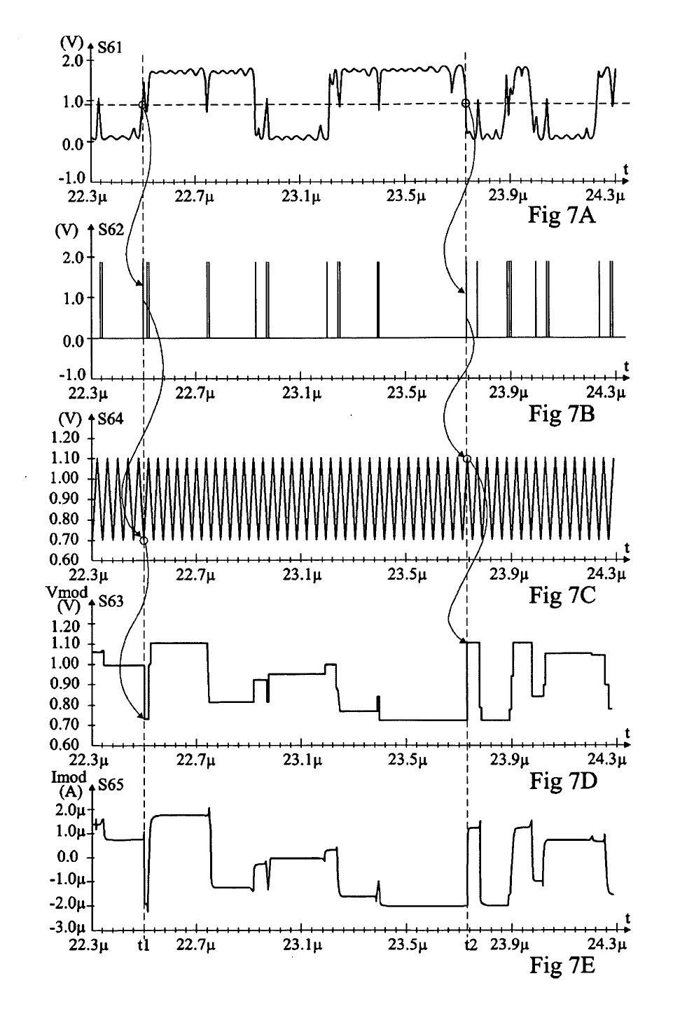

FIGS. 7A, 7B, 7C, 7D, and 7E illustrate, in timing diagrams, the operation of the circuit of FIG. 5. These drawings show examples of the shape, respectively of output S61 of chaotic oscillator 61, of output S62 of threshold detector 62, of output S64 of analog generator 64, of output S63 of sample-and-hold circuit 63, and of output current /mod S65 of converter 65 modulating the bias current of oscillator 2. In FIGS. 7A to 7E, two vertical dotted lines show times t1 and t2.

In this example, a threshold of detector 62 at a 900-millivolt level on a 1.8-volt amplitude range of signal S61 is assumed. Each time signal S61 crosses the threshold, be it in one direction or another, detector 62 provides an edge on its output S62.

Such edges are used to sample triangular signal S64. At output S63 of the sample-and-hold circuit, a stepped signal Vmod having not only its amplitude varying continuously within the range of possible voltages (here, of approximately 600 millivolts to 1.2 volts) set by the amplitude of signal S64, but also its duration varying continuously within the range of possible values (here, from approximately 25 to 2000 nanoseconds) is obtained. This range of durations is set by the range of possible intervals between jumps from one scroll attractor to the other of the chaotic oscillator (values of capacitors C1, C3, and C7 and the transconductance of the CMOS transistors of FIG. 5) which conditions the range of possible intervals between two edges of signal S62 of the threshold detector.

Bias current /pol of oscillator 2 is directly linked to stepped signal /mod (S65). Since this signal is pseudo-random with a continuous time and amplitude variation, the same holds true for the biasing of oscillator 2. Thus, output signal Vout provided by the oscillator exhibits an equiprobable pseudo-random character. A pseudo-random digital data flow (not shown) is then obtained, with an average value of the time intervals smaller than the oscillator stabilizabon time.

In the case of an average value of the intervals between frequency jumps greater than the oscillator stabilizabon time, its output transits in quasi-random fashion between steady pseudo-random states. A dock signal that may be used to dock a digital system (for example, a cryptographic system) to mask these current signatures is then obtained.

An electronic system such as a computer system may include the circuit of FIG. 5 to, e.g., encrypt data or to generate pseudo-random numbers. The system may include a circuit for sampling the output Vout from the oscillator 2 to generate a pseudo-random stream of binary values, or may use Vout as a clock signal having a frequency that varies in a pseudo random manner as discussed above in conjunction with FIGS. 5-7E.

Of course, the present invention is likely to have various alterations, improvements, and modificabons which will readily occur to those skilled in the art. In particular, the practical forming of the circuits forming a generator according to an embodiment of the present invention is within the abilities of those skilled in the art based on the functonli indications given hereabove, using circuits known per se. Further, the selection of the frequencies of the dfferent signals to obtain the pseudo-random digital flow according to the application is also within the abilities of those skilled in the art.

Such alterations, modificabons, and improvements are intended to be part of this disclosure, and are intended to be within the spirit and the scope of the present invention. Accordingly, the foregoing description is by way of example only and is not intended to be limiting.

What is claimed is:

1. A generator of a pseudo-random digital flow comprising a controllable-bias oscillator, and comprising an analog bias source controlled by a signal with continuous amplitude and time variations, said bias being controlled by a circuit for sampling/holding a periodic signal with more than two amplitude levels.

2. The generator of daim 1, wherein the sampling times of said bias source are set by a threshold detector of a pseudo-random signal source.

3. The generator of claim 2, wherein the periodic signal is provided by a triangular generator.

4. The generator of daim 3, wherein the amplitude range of the bias source is set by the amplitude of the triangular signal.

5. The generator of claim 2, wherein said source of a pseudorandom signal is a chaotic oscillator, preferably with several scroll attractors.

6. The generator of claim 5, wherein the range of the time variations of the biasing of the controllable-bias oscillator is set by the range of possible intervals between the jumps from one scroll attractor to another of the chaotic oscillator.

7. The generator of daim 1, wherein the maximum value of the range of time variations of the biasing of the controllable-bias oscillator is selected to be smaller than the stabilization time of this oscillator, to obtain a generator of pseudo-random digital data.

8. The generator of claim 1, wherein the minimum value of the range of time variations of the biasing of the controllable-bias oscillator is selected to be greater than the stabilization time of this oscillator to obtain a clock signal generator with pseudo-random frequency jumps.

9. A method for controlling the generator of a pseudo-random digital flow of claim 1, comprising the control of the biasing of the biasable oscillator by means of a stepped signal, where the duration of the steps varies in pseudo-random continuous fashion within a given interval and where the amplitude of the steps also varies in pseudo-random and continuous fashion within a given interval.

10. A circuit, comprising:
a first oscillator operable to receive a bias signal and to generate an output signal having a frequency that is related to the bias signal; and
a bias-signal generator coupled to the oscillator, operable to receive a clock signal having a pseudo-randomly varying period, and operable to vary the bias signal within a range of more than two continuous values in response to the clock signal.

11. The circuit of claim 10 wherein the bias signal comprises a bias current.

12. The circuit of claim 10 wherein the bias-signal generator comprises:
a second oscillator operable to generate a periodic signal; and
a sample and hold coupled to the second oscillator, operable to generate analog samples of the periodic signal in response to the clock signal, and operable to generate the bias signal from the samples of the periodic signal.

13. The circuit of claim 10 wherein the bias-signal generator comprises:
a second oscillator operable to generate a periodic voltage signal;
a sample and hold coupled to the second oscillator and operable to generate analog samples of the periodic voltage signal in response to the clock signal;
a source operable to generate a substantially constant current; and
a voltage-to-current converter operable to convert the samples into a modifier current and to generate the bias signal equal to a sum of the constant current and the modifier current.

14. The circuit of claim 10, further comprising a dock-signal generator having:
a source operable to generate a signal having an amplitude that varies pseudo randomly; and
a detector coupled to the source and operable to generate a pulse of the clock signal in response to the amplitude of the signal crossing a predetermined threshold voltage.

15. The circuit of claim 10, further comprising a clock-signal generator having:
a second, chaotic oscillator operable to generate a signal having an amplitude that varies pseudo randomly; and
a detector coupled to the source and operable to generate a pulse of the clock signal in response to the amplitude of the signal crossing a predetermined threshold voltage.

16. The circuit of claim 10 wherein:
the first oscillator has a settling time; and
the period of the clock signal has a maximum duration that is less than or equal to the settling time.

17. The circuit of claim 10 wherein:
the first oscillator has a settling time; and
the period of the clock signal has a minimum duration that is greater than the settling time.

18. A system, comprising:
a circuit, including,
an oscillator operable to receive a bias signal and to generate an output signal having a frequency that is related to the bias signal, and
a bias-signal generator coupled to the oscillator, operable to receive a clock signal having a pseudo-randomly varying period, and operable to vary the bias signal within a range of more than two continuous values in response to the dock signal.

19. The system of claim 18, further comprising:
wherein the oscillator has a setting time;
wherein the period of the dock signal has a maximum duration that is less than or equal to the settling time; and
a sampler operable to generate digital samples of the output signal at substantially uniforrn intervals.

20. The system of claim 18 wherein:
the first oscillator has a settling time; and
the period of the clock signal has a minimum duration that is greater than the settling time such that the output signal includes pseudo-random frequency jumps.

21. A method, comprising:
generating a bias signal that varies within a range of more than two continuous values in response to a clock signal having a pseudo-randomly varying period; and
generating a pseudo-random signal having a frequency that is related to the bias signal.

22. The method of claim 21 wherein varying the bias signal comprises:
generating a periodic signal;
generating analog samples of the periodic signal in response to the clock signal; and
generating the bias signal from the samples of the periodic signal.

23. The method of claim 21, further comprising generating the clock signal by:
generating a signal having an amplitude that varies pseudo randomly; and
beginning a period of the clock signal each time the amplitude of the signal crosses a predetermined threshold.

24. The method of claim 21, further comprising:
sampling the pseudo-random signal at a substantially constant sampling frequency to generate samples of the signal; and
generating a stream of pseudo-random digital values from the samples.
